(19) United States
(12) Patent Application Publication
(10) Pub. No.: US 2025/0240053 A1
(43) Pub. Date: Jul. 24, 2025

(54) INFORMATION PROCESSING DEVICE

(71) Applicant: NIDEC INSTRUMENTS CORPORATION, Nagano (JP)

(72) Inventors: Shinya MIYAZAWA, Nagano (JP); Junro TAKEUCHI, Nagano (JP)

(21) Appl. No.: 19/026,383

(22) Filed: Jan. 17, 2025

(30) Foreign Application Priority Data
Jan. 18, 2024 (JP) 2024-005803

(51) Int. Cl. H04B 5/40; H05K 1/02; H05K 1/18; H05K 7/14

(52) U.S. Cl. CPC H04B 5/40; H05K 1/0277; H05K 1/189; H05K 7/1427; H05K 2201/10098; H05K 2201/10128

(57) ABSTRACT

An information processing device to perform non-contact and manual information communication with a communication target includes a front surface portion that constitutes a front surface of the information processing device and over which the communication target is held, and a flexible printed circuit on which a communication antenna is mounted and disposed on a back surface side of the front surface portion. The flexible printed circuit is formed in a rectangular frame shape, which is constituted by a pair of straight long side portions and a pair of straight short side portions shorter than the long side portions. The thickness direction of the short side portions coincides with the front-rear direction, and the long side portions are bent toward the back side with respect to the short side portions, and the short side portions are disposed further to the front side than the long side portions.

### CROSS REFERENCE TO RELATED APPLICATION

The present invention claims priority under 35 U.S.C. § 119 to Japanese Application No. 2024-005803 filed Jan. 18, 2024, the entire content of which is incorporated herein by reference.

### BACKGROUND

### Field of the Invention

At least an embodiment of the present invention relates to an information processing device.

### Description of the Related Documents

Conventionally, a non-contact information processing device for communicating information with a non-contact integrated circuit (IC) card in a non-contact and manual manner is known (for example, see WO 2022/018929). The non-contact information processing device described in WO 2022/018929 includes an aerial image display device that displays an aerial image in a three dimensional space, a detection mechanism for detecting a position of a fingertip of a user in an aerial image display area that is an area where the aerial image is displayed, a housing that houses the aerial image display device and the detection mechanism, and a flexible printed circuit on which a communication antenna is mounted. The housing includes a plate-like frame body surrounding the aerial image display area. The frame body constitutes a front upper surface of the housing. The inner peripheral side of the frame body serves as an opening portion communicating with the inside of the housing. The aerial image display area is formed in the opening portion.

In the non-contact information processing device described in WO 2022/018929, the flexible printed circuit is formed in a rectangular frame shape. The flexible printed circuit is fixed to a rear lower surface of the frame body. The flexible printed circuit is disposed on the outer peripheral side of the opening portion so as to surround the opening portion of the frame body. The thickness direction of the flexible printed circuit coincides with the thickness direction of the frame body. In the non-contact information processing device described in WO 2022/018929, the user holds an IC card over the frame body using a mark displayed in the aerial image display area as a guide, and information communication can be thereby performed in a non-contact manner between the non-contact information processing device and the IC card.

In the non-contact information processing device described in WO 2022/018929, the communication antenna is mounted on the flexible printed circuit formed in the rectangular frame shape, and a distance between a part of the antenna mounted on a long side portion of the flexible printed circuit and the center of the antenna is shorter than a distance between a part of the antenna mounted on a short side portion of the flexible printed circuit and the center of the antenna. Further, in this non-contact information processing device, the thickness direction of the flexible printed circuit coincides with the thickness direction of the frame body.

Therefore, in the non-contact information processing device described in WO 2022/018929, when a current flows through the antenna, on the front upper side of the non-contact information processing device over which the IC card is held, the strength of the magnetic field generated from the long side portion of the flexible printed circuit at the center of the antenna is stronger than the strength of the magnetic field generated from the short side portion of the flexible printed circuit at the center of the antenna. Consequently, in this non-contact information processing device, when a current flows through the antenna, on the front upper side of the non-contact information processing device over which the IC card is held, the strength of the magnetic field generated from the long side portion of the flexible printed circuit at the center of the antenna and the strength of the magnetic field generated from the short side portion of the flexible printed circuit at the center of the antenna are unbalanced, and the communication characteristics between the antenna mounted on the flexible printed circuit and the IC card may deteriorate.

Accordingly, an object of at least an embodiment of the present invention is to provide an information processing device to perform non-contact and manual information communication with a communication target, which enables to suppress deterioration in communication characteristics between a communication antenna and the communication target even when the communication antenna is mounted on a flexible printed circuit formed in a rectangular or oval frame shape.

### SUMMARY

In order to solve the above problem, an information processing device according to a mode of at least an embodiment of the present invention is an information processing device to perform non-contact and manual information communication with a communication target, and includes a front surface portion that constitutes a front surface of the information processing device and over which the communication target is held, and a flexible printed circuit on which a communication antenna is mounted and which is disposed on a back surface side of the front surface portion. The flexible printed circuit is formed in a rectangular or oval frame shape, which is constituted by a pair of straight long side portions and a pair of straight or arc-shaped short side portions shorter than the long side portions. A direction orthogonal to the front surface is a first direction, a side in the first direction on which the front surface is disposed is a front side, and a side opposite to the front side is a back side. A thickness direction of the short side portions coincides with the first direction, and the long side portions are bent toward the back side with respect to the short side portions, and the short side portions are disposed further to the front side than the long side portions, or a thickness direction of the long side portions coincides with the first direction, and the short side portions are bent toward the front side with respect to the long side portions, and the short side portions are disposed further to the front side than the long side portions.

In the information processing device according to this mode, the flexible printed circuit, which is disposed on the back surface side of the front surface portion over which the communication target is held and on which the antenna is mounted, is formed in a rectangular or oval frame shape constituted by a pair of long side portions and a pair of short side portions. Further, in this mode, the long side portions are bent toward the back side with respect to the short side portions whose thickness direction coincides with the first direction, and the short side portions are disposed further to the front side than the long side portions, or the short side portions are bent toward the front side with respect to the long side portions whose thickness direction coincides with the first direction, and the short side portions are disposed further to the front side than the long side portions.

Therefore, in this mode, even when a distance between a part of the antenna mounted on the long side portions and the center of the antenna is shorter than a distance between a part of the antenna mounted on the short side portions and the center of the antenna, when a current flows through the antenna, on the front side of the information processing device over which the communication target is held, the difference between the strength of the magnetic field generated from the long side portions at the center of the antenna and the strength of the magnetic field generated from the short side portions at the center of the antenna is suppressed, and it becomes possible to suppress the imbalance between the strength of the magnetic field generated from the long side portions at the center of the antenna and the strength of the magnetic field generated from the short side portions at the center of the antenna. Consequently, in this mode, it is possible to suppress deterioration in communication characteristics between a communication antenna and the communication target even when the communication antenna is mounted on a flexible printed circuit formed in a rectangular or oval frame shape.

As described above, according to a mode of at least an embodiment of the present invention, in an information processing device to perform non-contact and manual information communication with a communication target, it is possible to suppress deterioration in communication characteristics between a communication antenna and the communication target even when the communication antenna is mounted on a flexible printed circuit formed in a rectangular or oval frame shape.

### BRIEF DESCRIPTION OF THE DRAWINGS

Embodiments will now be described, by way of example only, with reference to the accompanying drawings which are meant to be exemplary, not limiting, and wherein like elements are numbered alike in several figures, in which:

FIG. 1 is a perspective view of an information processing device according to at least an embodiment of the present invention;

FIG. 2 is an exploded perspective view of a configuration of a part of the information processing device illustrated in FIG. 1;

FIG. 3 is a perspective view illustrating a front surface portion and a flexible printed circuit of the information processing device illustrated in FIG. 1, which are extracted and viewed from a back surface side;

FIG. 4 is an exploded perspective view of the front surface portion and the flexible printed circuit illustrated in FIG. 3;

FIG. 5 is a perspective view of a flexible printed circuit according to another embodiment of the present invention; and

FIG. 6 is a diagram for explaining a configuration of the flexible printed circuit according to another embodiment of the present invention.

### DETAILED DESCRIPTION

Hereinafter, at least an embodiment of the present invention will be described with reference to the drawings.

### Configuration of Information Processing Device

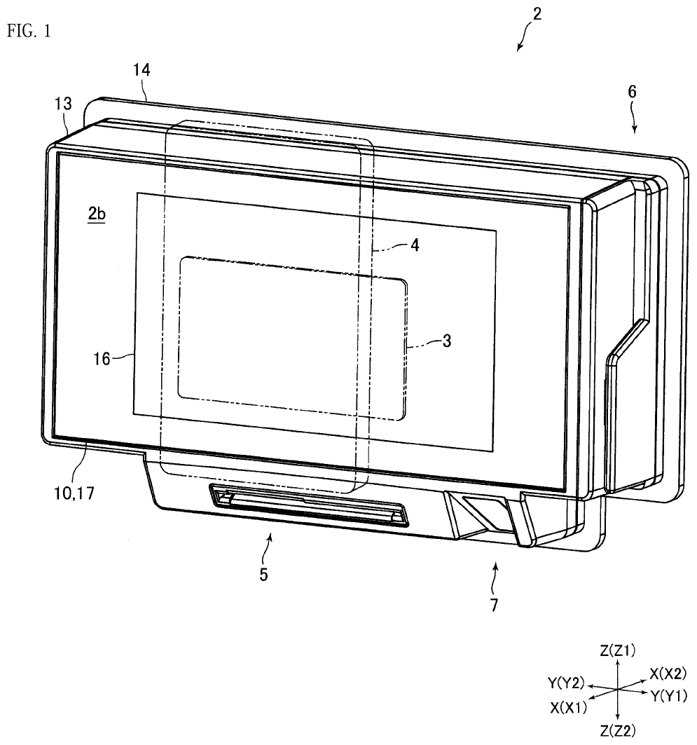

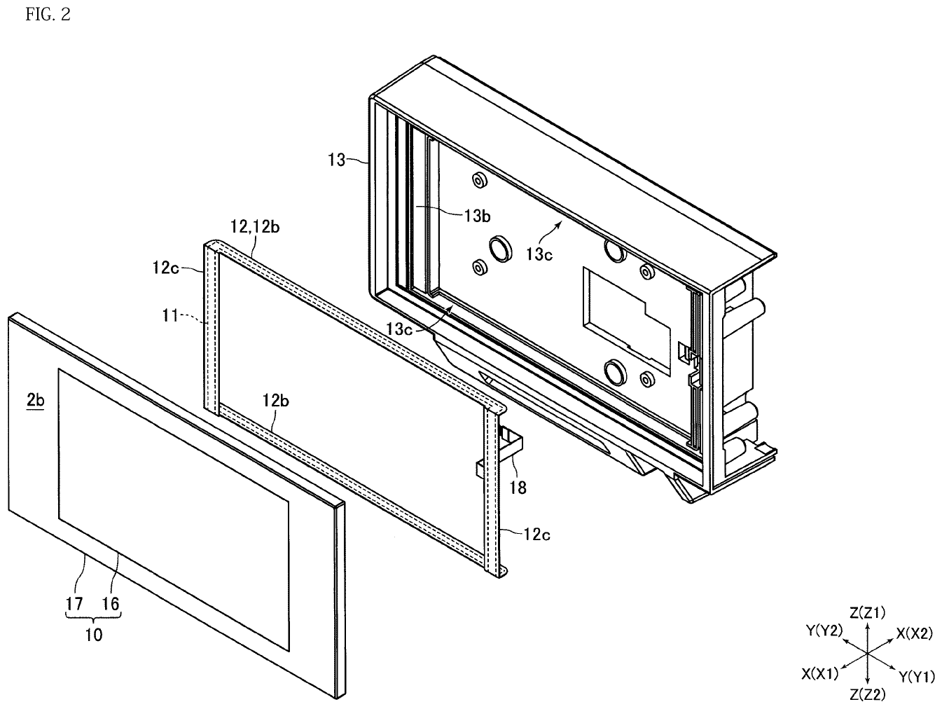

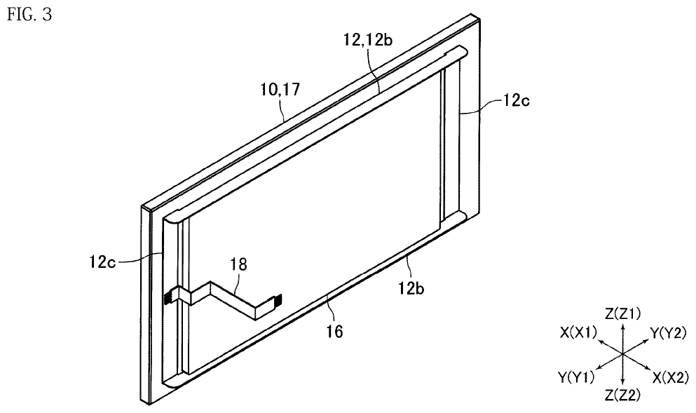

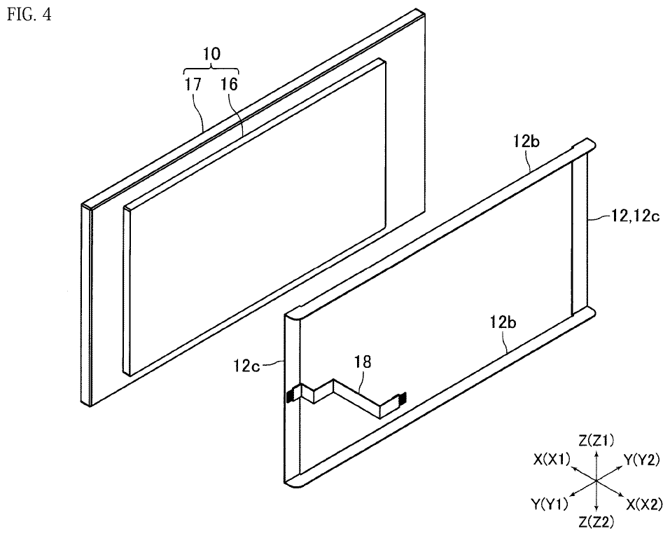

FIG. 1 is a perspective view of an information processing device 2 according to at least an embodiment of the present invention. FIG. 2 is an exploded perspective view of a configuration of a part of the information processing device 2 illustrated in FIG. 1. FIG. 3 is a perspective view illustrating a front surface portion 10 and a flexible printed circuit 12 extracted from the information processing device 2 illustrated in FIG. 1 as viewed from the back surface side. FIG. 4 is an exploded perspective view of the front surface portion 10 and the flexible printed circuit 12 illustrated in FIG. 3.

In the following description, for convenience of description, a Z direction in FIG. 1 and the like is an up-down direction, an X direction in FIG. 1 and the like orthogonal to the up-down direction is a front-rear direction, and a Y direction in FIG. 1 and the like orthogonal to the up-down direction and the front-rear direction is a left-right direction. Further, a Z1 direction side in FIG. 1 and the like, which is one direction side in the up-down direction, is referred to as “upper” side, while a Z2 direction side in FIG. 1 and the like, which is a side opposite to the upper side, as “lower” side; an X1 direction side in FIG. 1 and the like, which is one direction side in the front-rear direction, as “front” side, while an X2 direction side in FIG. 1 and the like, which is a side opposite to the front side, as a “rear” side; and a Y1 direction side in FIG. 1 and the like, which is one direction side in the left-right direction, as “right” side, while a Y2 direction side in FIG. 1 and the like, which is a side opposite to the right side, as “left” side.

The information processing device 2 of the present embodiment is a device for non-contact and manual communication of information with a non-contact IC card 3 (hereinafter referred to as a “card 3”) or a smartphone 4, which is a communication target. The information processing device 2 is, for example, a payment terminal device used for payment. Further, the information processing device 2 is used by being mounted on a higher-level apparatus such as an automatic ticketing machine, a vending machine, an entrance/exit management apparatus, or an automatic teller machine (ATM). The information processing device 2 of the present embodiment also has a function as an input device to which information is input using a user's fingertip or the like. For example, a password or a personal identification number (PIN) is input to the information processing device 2.

Each of the card 3 and the smartphone 4 includes an IC chip and a communication antenna electrically connected to the IC chip. In the information processing device 2, a card 3 which is a contact IC card or a card 3 which is a magnetic card may be used. That is, an external connection terminal of an IC chip or a magnetic stripe may be formed on the card 3 used in the information processing device 2. The card 3 is a card conforming to international standards and Japanese Industrial Standards (JIS), and is smaller than the smartphone 4.

The information processing device 2 is formed in a flat and substantially rectangular parallelepiped shape having a small thickness in the front-rear direction as a whole. The outer shape of the information processing device 2 when viewed from the front-rear direction is a substantially rectangular shape having a long side in the left-right direction. In the present embodiment, the user who uses the information processing device 2 performs various operations from the front side of the information processing device 2. The front surface of the information processing device 2 is a front surface 2b which is a plane orthogonal to the front-rear direction. That is, the user who uses the information processing device 2 performs various operations from the front surface 2b side. The front-rear direction (X direction) of the present embodiment is a first direction which is a direction orthogonal to the front surface 2b. Further, a front side (X1 direction side) is a front side which is a side on which the front surface 2b is disposed in the first direction, and a rear side (X2 direction side) is a back side which is a side opposite to the front side.

The information processing device 2 includes, as functional components, an IC card processing unit 5 for performing data communication with a contact IC card, a magnetic card processing unit 6 for reading magnetic data recorded in a magnetic card and recording magnetic data in the magnetic card, and a code reading unit 7 for reading a two dimensional code or the like displayed on the smartphone 4. Further, the information processing device 2 includes, as a structural configuration, a front surface portion 10 that forms the front surface 2b over which the card 3 that is a non-contact IC card or the smartphone 4 is held, a flexible printed circuit 12 (hereinafter referred to as “FPC 12”) on which a communication antenna 11 (see FIG. 2) for communicating information with the card 3 or the smartphone 4 in a non-contact manner is mounted, a housing 13 in which the FPC 12 is housed, and a rear surface portion 14 that constitutes the rear surface of the information processing device 2.

The IC card processing unit 5 is a manual dip-type card reader. The IC card processing unit 5 includes an IC contact block having a plurality of IC contact springs which come into contact with external connection terminals of a contact IC card. The magnetic card processing unit 6 is a manual swipe type card reader. The magnetic card processing unit 6 includes a magnetic head that reads and records magnetic data. The code reading unit 7 includes a camera for reading a two dimensional code or the like. The IC card processing unit 5 is disposed on the front surface side and the lower surface side of the information processing device 2. The magnetic card processing unit 6 is disposed at the right end portion of the information processing device 2. The code reading unit 7 is disposed on the front surface side and the lower surface side of the information processing device 2. Further, the code reading unit 7 is disposed on the right side of the IC card processing unit 5.

The front surface portion 10 includes a liquid crystal display 16 as a display on which an image is displayed, and a frame-shaped frame member 17 surrounding the liquid crystal display 16. The front surface portion 10 of the present embodiment is constituted by the liquid crystal display 16 and the frame member 17. The liquid crystal display 16 is a display with a touch panel, and has an information input function in addition to a display function. The liquid crystal display 16 is formed in a rectangular shape. The frame member 17 is formed of, for example, glass. The frame member 17 is formed in a rectangular frame shape. Further, the frame member 17 is formed in a flat plate shape.

The thickness direction of the liquid crystal display 16 and the thickness direction of the frame member 17 coincide with the front-rear direction. The direction of the long sides of the liquid crystal display 16 and the frame member 17 formed in a rectangular shape coincides with the left-right direction, and the direction of the short sides of the liquid crystal display 16 and the frame member 17 coincides with the up-down direction. The thickness of the liquid crystal display 16 is larger than that of the frame member 17. The front surface of the liquid crystal display 16 and the front surface of the frame member 17 are disposed on the same plane. The front surface 2b of the present embodiment is constituted by the front surface of the liquid crystal display 16 and the front surface of the frame member 17. The rear surface of the liquid crystal display 16 is disposed behind the rear surface of the frame member 17. The rear surface of the liquid crystal display 16 and the rear surface of the frame member 17 may be disposed on the same plane.

The FPC 12 is formed in a rectangular frame shape constituted by a pair of straight long side portions 12b parallel to each other and a pair of straight short side portions 12c shorter than the long side portions 12b. The long side portions 12b are parallel to the left-right direction, and the short side portions 12c are parallel to the up-down direction. The outer shape of the FPC 12 is larger than the outer shape of the liquid crystal display 16. The antenna 11 mounted on the FPC 12 is annularly wound along the long side portions 12b and the short side portions 12c. That is, the antenna 11 is an antenna coil (loop antenna) formed by annularly winding a coil.

In the FPC 12, the thickness direction of the short side portions 12c coincides with the front-rear direction. Further, in the FPC 12, the long side portions 12b are bent toward the rear side (back side) with respect to the short side portions 12c. That is, the short side portions 12c are disposed further to the front side than the long side portions 12b. In present embodiment, the long side portions 12b are bent at a right angle with respect to the short side portions 12c, and the thickness direction of the long side portions 12b coincides with the up-down direction.

The FPC 12 is disposed on the back surface side (rear surface side) of the front surface portion 10. To be specific, the FPC 12 is disposed on the back side (rear side) of the frame member 17. The short side portions 12c are in contact with the back surface (rear surface) of the frame member 17 orthogonal to the front-rear direction. That is, the FPC 12 is disposed on the outer peripheral side of the liquid crystal display 16, and surrounds the liquid crystal display 16 when viewed from the front-rear direction. To be specific, the FPC 12 surrounds the rear side portion of the liquid crystal display 16 disposed on the rear side of the back surface of the frame member 17. When viewed from the front-rear direction, the center of the FPC 12 coincides with the center of the liquid crystal display 16. A flexible printed circuit or a lead-out wire 18 formed of a flexible flat cable is connected to the rear surface of the short side portions 12c disposed on the right side. The wire 18 is routed from the FPC 12 toward the rear side.

The front surface portion 10 is fixed to a front end portion of the housing 13. Further, the FPC 12 is fixed to the housing 13. A fixing surface 13b to which the short side portions 12c are fixed is formed in the housing 13. The fixing surface 13b is a flat surface orthogonal to the front-rear direction. The short side portions 12c are fixed to the fixing surface 13b by, for example, a double-sided tape. In addition, an insertion portion 13c into which the long side portions 12b are inserted is formed in the housing 13. The insertion portion 13c is a slit-shaped recess into which a part of the long side portions 12b is inserted. The housing 13 houses a circuit board (not illustrated) to which the antenna 11, the liquid crystal display 16, and the like are electrically connected. This circuit board is, for example, a rigid board such as a glass epoxy board. The rear surface portion 14 is fixed to a rear end portion of the housing 13.

When the information processing device 2 performs data communication with the card 3 or the smartphone 4 in a non-contact manner, the user holds the card 3 or the smartphone 4 over the liquid crystal display 16 from the front side. At this time, for example, a predetermined mark for indicating the center position of the antenna 11 is displayed on the liquid crystal display 16. The mark is, for example, a logo mark (ripple mark) specified in Europay, MasterCard, and Visa (EMV), which is the international standard. The user holds the card 3 or the smartphone 4 over the liquid crystal display 16 using the mark displayed thereon as a guide.

Further, when the IC card processing unit 5 performs data communication with a contact IC card, the user inserts and removes the card 3 into and from the IC card processing unit 5 in the front-rear direction. When the magnetic card processing unit 6 reads magnetic data or the like, the user operates the card 3 downward with respect to the magnetic card processing unit 6. When a two dimensional code or the like is read by the code reading unit 7, the user holds the two dimensional code displayed on the smartphone 4 over the code reading unit 7, for example. Further, the password and the personal identification number are input on the liquid crystal display 16. When a password or a personal identification number is input, for example, keys of numerals from “0” to “9” are displayed on the liquid crystal display 16. The user touches the liquid crystal display 16 to input a password or the like.

### Main Effect of Present Embodiment

As described above, in the present embodiment, the FPC 12 which is constituted by a pair of long side portions 12b and a pair of short side portions 12c and on which the antenna 11 is mounted is disposed on the back surface side of the front surface portion 10 over which the card 3 or the smartphone 4 is held. Further, in the present embodiment, the long side portions 12b are bent toward the back side with respect to the short side portions 12c whose thickness direction coincides with the front-rear direction, and the short side portions 12c are disposed further to the front side than the long side portions 12b.

Therefore, in the present embodiment, even when the distance between a part of the antenna 11 mounted on the long side portions 12b and the center of the antenna 11 is shorter than the distance between a part of the antenna 11 mounted on the short side portions 12c and the center of the antenna 11, when a current flows through the antenna 11, on the front side of the information processing device 2 over which the card 3 or the smartphone 4 is held, the difference between the strength of the magnetic field generated from the long side portions 12b at the center of the antenna 11 and the strength of the magnetic field generated from the short side portions 12c at the center of the antenna 11 is suppressed, and it becomes possible to suppress the imbalance between the strength of the magnetic field generated from the long side portions 12b at the center of the antenna 11 and the strength of the magnetic field generated from the short side portions 12c at the center of the antenna 11. Therefore, in the present embodiment, even when the antenna 11 is mounted on the FPC 12 formed in a rectangular frame shape, it is possible to suppress deterioration in communication characteristics between the card 3 or the smartphone 4 and the antenna 11.

In particular, in the present embodiment, since the thickness direction of the short side portions 12c coincides with the front-rear direction, when a current flows through the antenna 11, on the front side of the information processing device 2, it is possible to further increase the strength of the magnetic field generated from the short side portions 12c at the center of the antenna 11 relative to the strength of the magnetic field generated from the long side portions 12b at the center of the antenna 11. Further, in the present embodiment, since the long side portions 12b are bent at a right angle with respect to the short side portions 12c, when a current flows through the antenna 11, on the front side of the information processing device 2, it becomes possible to further reduce the strength of the magnetic field generated from the long side portions 12b at the center of the antenna 11 relative to the strength of the magnetic field generated from the short side portions 12c at the center of the antenna 11.

Therefore, in the present embodiment, when a current flows through the antenna 11, on the front side of the information processing device 2, the difference between the strength of the magnetic field generated from the long side portions 12b at the center of the antenna 11 and the strength of the magnetic field generated from the short side portions 12c at the center of the antenna 11 is effectively suppressed, and it becomes possible to effectively suppress the imbalance between the strength of the magnetic field generated from the long side portions 12b at the center of the antenna 11 and the strength of the magnetic field generated from the short side portions 12c at the center of the antenna 11.

Further, in the present embodiment, since the long side portions 12b are bent toward the back side with respect to the short side portions 12c, it is possible to reduce the size of the FPC 12 in the up-down direction. In particular, in the present embodiment, since the long side portions 12b are bent at a right angle with respect to the short side portions 12c, it is possible to further reduce the size of the FPC 12 in the up-down direction while preventing interference between the long side portions 12b and other components.

In the present embodiment, the FPC 12 is disposed on the outer peripheral side of the liquid crystal display 16, and surrounds the liquid crystal display 16 when viewed from the front-rear direction. Therefore, in the present embodiment, the antenna 11 mounted on the FPC 12 is less likely to be affected by the magnetic field generated from the liquid crystal display 16. Therefore, in the present embodiment, even when the front surface portion 10 is provided with the liquid crystal display 16, it is possible to suppress deterioration in communication characteristics between the card 3 or the smartphone 4 and the antenna 11.

In the present embodiment, the short side portions 12c are in contact with the back surface of the frame member 17, and is disposed closer to the front surface 2b of the information processing device 2. Therefore, in the present embodiment, when a current flows through the antenna 11, on the front side of the information processing device 2, it is possible to increase the strength of the magnetic field generated from the short side portions 12c at the center of the antenna 11. Further, in the present embodiment, since the fixing surface 13b to which the short side portions 12c are fixed and the insertion portion 13c into which the long side portions 12b are insertion are formed in the housing 13, it is possible to stabilize the state of the FPC 12 disposed on the back surface side of the front surface portion 10.

### Modification of Flexible Printed Circuit

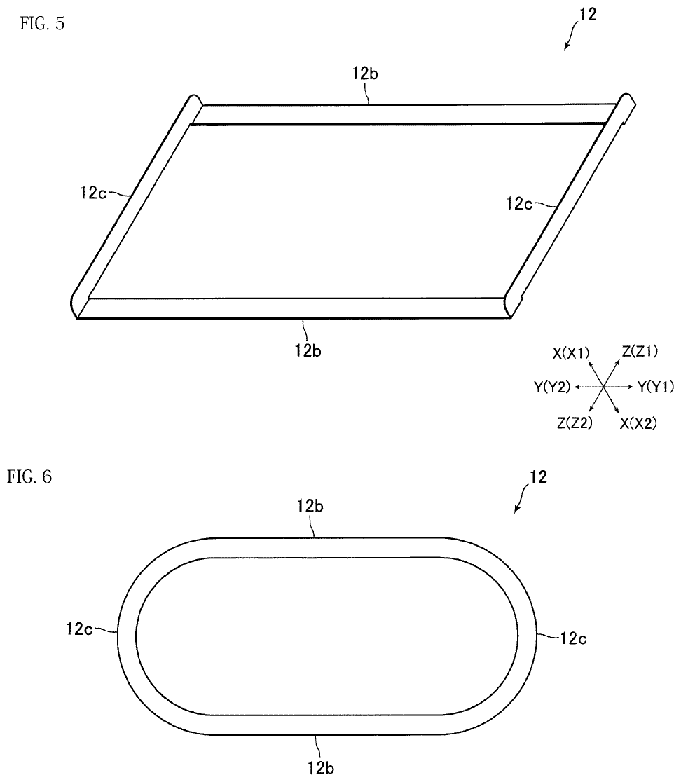

FIG. 5 is a perspective view of an FPC 12 according to another embodiment of the present invention. FIG. 6 is a diagram for explaining a configuration of the FPC 12 according to another embodiment of the present invention.

In the above-described embodiment, the thickness direction of the long side portions 12b may coincide with the front-rear direction, the short side portions 12c may be bent toward the front side with respect to the long side portions 12b, and the short side portions 12c may be disposed further to the front side than the long side portions 12b (see FIG. 5). In this case, for example, the short side portions 12c are bent at a right angle with respect to the long side portions 12b.

Even in this case, since the short side portions 12c are disposed further to the front side than the long side portions 12b, when a current flows through the antenna 11, on the front side of the information processing device 2, the difference between the strength of the magnetic field generated from the long side portions 12b at the center of the antenna 11 and the strength of the magnetic field generated from the short side portions 12c at the center of the antenna 11 is suppressed, and it becomes possible to suppress the imbalance between the strength of the magnetic field generated from the long side portions 12b at the center of the antenna 11 and the strength of the magnetic field generated from the short side portions 12c at the center of the antenna 11. Further, in this case, it is possible to reduce the size of the FPC 12 in the left-right direction.

Furthermore, in the above-described embodiment, as illustrated in FIG. 6, the FPC 12 may be formed in an oval frame shape constituted by a pair of long side portions 12b and a pair of arc-shaped short side portions 12c shorter than the long side portions 12b. In this case, for example, the thickness direction of the short side portions 12c coincides with the front-rear direction, and the long side portions 12b are bent toward the back side with respect to the short side portions 12c. Further, the thickness direction of the long side portions 12b may coincide with the front-rear direction, and the short side portions 12c may be bent toward the front side with respect to the long side portions 12b.

Even in this case, since the short side portions 12c are disposed further to the front side than the long side portions 12b, when a current flows through the antenna 11, on the front side of the information processing device 2, the difference between the strength of the magnetic field generated from the long side portions 12b at the center of the antenna 11 and the strength of the magnetic field generated from the short side portions 12c at the center of the antenna 11 is suppressed, and it becomes possible to suppress the imbalance between the strength of the magnetic field generated from the long side portions 12b at the center of the antenna 11 and the strength of the magnetic field generated from the short side portions 12c at the center of the antenna 11.

In a case where the FPC 12 is formed in a rectangular frame shape as in the above-described embodiment, when the long side portions 12b are bent toward the back side with respect to the short side portions 12c, it is possible to reduce the size of the FPC 12 in the left-right direction while ensuring the length of the long side portions 12b, as compared with a case where the FPC 12 is formed in an oval frame shape. Further, in a case where the FPC 12 is formed in a rectangular frame shape, when the short side portions 12c are bent toward the front side with respect to the long side portions 12b, it is possible to reduce the size of the FPC 12 in the front-rear direction, as compared with a case where the FPC 12 is formed in an oval frame shape. Furthermore, even if the FPC 12 is formed in an oval frame shape, in a case where the long side portions 12b are bent toward the back side with respect to the short side portions 12c, it is possible to reduce the size of the FPC 12 in the front-rear direction, as compared with a case where the short side portions 12c are bent toward the front side with respect to the long side portions 12b.

### Other Embodiments

The above-described embodiment is an example of a preferable exemplary embodiment of the present invention, but the present invention is not limited thereto, and various modifications can be made without departing from the scope of the present invention.

In the above-described embodiment, the long side portions 12b may be bent at an obtuse angle or an acute angle with respect to the short side portions 12c. In addition, in the modification illustrated in FIG. 5, the short side portions 12c may be bent at an obtuse angle or an acute angle with respect to the long side portions 12b. Further, in the above-described embodiment, the center of the FPC 12 and the center of the liquid crystal display 16 may be shifted from each other when viewed from the front-rear direction.

Furthermore, in the above-described embodiment, the outer shape of the FPC 12 may be smaller than the outer shape of the liquid crystal display 16. In this case, the FPC 12 may be disposed at a position overlapping the liquid crystal display 16 in the front-rear direction. That is, the FPC 12 may not be disposed so as to surround the liquid crystal display 16.

In the above-described embodiment, the liquid crystal display 16 may not have an information input function. That is, the liquid crystal display 16 may not include a touch panel. Further, in the above-described embodiment, the front surface portion 10 may include a display other than the liquid crystal display 16, such as an organic electroluminescent (EL) display. Furthermore, in the above-described embodiment, the front surface portion 10 may not include the display. In this case, the front surface portion 10 is, for example, a rectangular flat plate formed of resin or glass, and the information processing device 2 does not have a function as an input device.

Further, in a case where the front surface portion 10 is not provided with a display, an opening on the inner peripheral side of the frame member 17 may be an aerial image display area which is an area where an aerial image is displayed. In this case, similarly to the non-contact information processing device described in WO 2022/018929, the information processing device 2 includes an aerial image display device and a detection mechanism, and the aerial image display area serves as an information input unit for the user to input information such as a password using a fingertip.

In the above-described embodiment, the information processing device 2 may not include at least one of the IC card processing unit 5, the magnetic card processing unit 6, and the code reading unit 7. Further, in the above-described embodiment, the communication target with which information is communicated with the information processing device 2 may be an information recording medium other than the card 3, or may be an electronic device other than the smartphone 4, such as a Radio Frequency Identification (RFID) tag.

### Configuration of Present Technique

The present technique may be configured as follows.
(1) An information processing device to perform non-contact and manual information communication with a communication target includes a front surface portion that constitutes a front surface of the information processing device and over which the communication target is held, and a flexible printed circuit on which a communication antenna is mounted and which is disposed on a back surface side of the front surface portion. The flexible printed circuit is formed in a rectangular or oval frame shape, which is constituted by a pair of straight long side portions and a pair of straight or arc-shaped short side portions shorter than the long side portions. A direction orthogonal to the front surface is a first direction, a side in the first direction on which the front surface is disposed is a front side, and a side opposite to the front side is a back side. A thickness direction of the short side portions coincides with the first direction, and the long side portions are bent toward the back side with respect to the short side portions, and the short side portions are disposed further to the front side than the long side portions, or a thickness direction of the long side portions coincides with the first direction, and the short side portions are bent toward the front side with respect to the long side portions, and the short side portions are disposed further to the front side than the long side portions.
(2) The information processing device according to (1), in which the flexible printed circuit is formed in a rectangular frame shape.
(3) The information processing device according to (1) or (2), in which a thickness direction of the short side portions coincides with the first direction, and the long side portions are bent toward a back side with respect to the short side portions.
(4) The information processing device according to (3), in which the long side portions are bent at a right angle with respect to the short side portions.
(5) The information processing device according to (3) or (4), in which the front surface portion includes a rectangular display on which an image is displayed, and in which the flexible printed circuit is disposed on an outer peripheral side of the display and surrounds the display when viewed from the first direction.
(6) The information processing device according to (5), in which the front surface portion includes a frame-shaped frame member surrounding the display, and in which the short side portions are in contact with a back surface of the frame member.
(7) The information processing device according to any of (3) to (6), further including a housing in which the flexible printed circuit is housed, in which the housing has a fixing surface to which the short side portions are fixed and an insertion portion into which the long side portions are inserted.

In this mode, the flexible printed circuit is preferably formed in a rectangular frame shape. With this configuration, in a case where the long side portions are bent toward the back side with respect to the short side portions, it is possible to reduce the size of the flexible printed circuit in the direction parallel to the long side portions while ensuring the length of the long side portions, as compared with a case where the flexible printed circuit is formed in an oval frame shape. Further, with this configuration, in a case where the short side portions are bent toward the front side with respect to the long side portions, it is possible to reduce the size of the flexible printed circuit in the first direction, as compared with a case where the flexible printed circuit is formed in an oval frame shape.

In this mode, it is preferable that the thickness direction of the short side portions coincide with the first direction, and that the long side portions be bent toward the back side with respect to the short side portion. With this configuration, since the thickness direction of the short side portions coincides with the first direction, when a current flows through the antenna, on the front side of the information processing device, it is possible to further increase the strength of the magnetic field generated from the short side portions at the center of the antenna relative to the strength of the magnetic field generated from the long side portions at the center of the antenna. Therefore, when a current flows through the antenna, on the front side of the information processing device, the difference between the strength of the magnetic field generated from the long side portions at the center of the antenna and the strength of the magnetic field generated from the short side portions at the center of the antenna is effectively suppressed, and it becomes possible to effectively suppress the imbalance between the strength of the magnetic field generated from the long side portions at the center of the antenna and the strength of the magnetic field generated from the short side portions at the center of the antenna.

Further, with this configuration, since the long side portions are bent toward the back side with respect to the short side portions, it is possible to reduce the size of the flexible printed circuit in the direction orthogonal to the direction parallel to the long side portions and the first direction. Furthermore, with this configuration, since the short side portions are not bent, even if the flexible printed circuit is formed in an oval frame shape, it is possible to reduce the size of the flexible printed circuit in the first direction.

In this mode, the long side portions are preferably bent at a right angle with respect to the short side portions. With this configuration, when a current flows through the antenna, on the front side of the information processing device, it is possible to further reduce the strength of the magnetic field generated from the long side portions at the center of the antenna relative to the strength of the magnetic field generated from the short side portions at the center of the antenna. Therefore, when a current flows through the antenna, on the front side of the information processing device, it is possible to more effectively suppress the difference between the strength of the magnetic field generated from the long side portions at the center of the antenna and the strength of the magnetic field generated from the short side portions at the center of the antenna. Further, with this configuration, it is possible to reduce the size of the flexible printed circuit in the direction orthogonal to the direction parallel to the long side portions and the first direction while preventing interference between the long side portions and other components.

In this mode, for example, the front surface portion includes a rectangular display on which an image is displayed, and the flexible printed circuit is disposed on the outer peripheral side of the display and surrounds the display when viewed from the first direction. In this case, the antenna mounted on the flexible printed circuit is less likely to be affected by the magnetic field generated from the display. Consequently, even if the front surface portion includes a display, it is possible to suppress deterioration in communication characteristics between the antenna mounted on a flexible printed circuit and the communication target.

In this mode, for example, the front surface portion includes a frame-shaped frame member surrounding the display, and the short side portions are in contact with a back surface of the frame member. In this case, since the short side portions are disposed closer to the front surface side of the information processing device, when a current flows through the antenna, on the front surface side of the information processing device, it is possible to further increase the strength of the magnetic field generated from the short side portions at the center of the antenna.

In this mode, it is preferable that the information processing device further include a housing in which the flexible printed circuit is housed, and that the housing have a fixing surface to which the short side portions are fixed and an insertion portion into which the long side portions are inserted. With this configuration, it is possible to stabilize the state of the flexible printed circuit disposed on the back surface side of the front surface portion.

What is claimed is:

1. An information processing device to perform non-contact and manual information communication with a communication target, the information processing device comprising:
a front surface portion that constitutes a front surface of the information processing device and over which the communication target is held; and
a flexible printed circuit on which a communication antenna is mounted and which is disposed on a back surface side of the front surface portion,
wherein the flexible printed circuit is formed in a rectangular or oval frame shape, which is constituted by a pair of straight long side portions and a pair of straight or arc-shaped short side portions shorter than the long side portions,
wherein when a direction orthogonal to the front surface is a first direction, a side in the first direction on which the front surface is disposed is a front side, and a side opposite to the front side is a back side,
a thickness direction of the short side portions coincides with the first direction, and the long side portions are bent toward the back side with respect to the short side portions, and the short side portions are disposed further to the front side than the long side portions; or a thickness direction of the long side portions coincides with the first direction, and the short side portions are bent toward the front side with respect to the long side portions, and the short side portions are disposed further to the front side than the long side portions.

2. The information processing device according to claim 1, wherein the flexible printed circuit is formed in a rectangular frame shape.

3. The information processing device according to claim 1, wherein a thickness direction of the short side portions coincides with the first direction, and the long side portions are bent toward a back side with respect to the short side portions.

4. The information processing device according to claim 3, wherein the long side portions are bent at a right angle with respect to the short side portions.

5. The information processing device according to claim 3,
wherein the front surface portion comprises a rectangular display on which an image is displayed, and
wherein the flexible printed circuit is disposed on an outer peripheral side of the display and surrounds the display when viewed from the first direction.

6. The information processing device according to claim 5,
wherein the front surface portion comprises a frame-shaped frame member surrounding the display, and
wherein the short side portions are in contact with a back surface of the frame member.

7. The information processing device according to claim 3, further comprising a housing in which the flexible printed circuit is housed, wherein the housing has a fixing surface to which the short side portions are fixed and an insertion portion into which the long side portions are inserted.

8. The information processing device according to claim 2, wherein a thickness direction of the short side portions coincides with the first direction, and the long side portions are bent toward a back side with respect to the short side portions.

9. The information processing device according to claim 8, wherein the long side portions are bent at a right angle with respect to the short side portions.

10. The information processing device according to claim 8,
wherein the front surface portion comprises a rectangular display on which an image is displayed, and
wherein the flexible printed circuit is disposed on an outer peripheral side of the display and surrounds the display when viewed from the first direction.

11. The information processing device according to claim 8,
wherein the front surface portion comprises a frame-shaped frame member surrounding the display, and
wherein the short side portions are in contact with a back surface of the frame member.

12. The information processing device according to claim 8, further comprising a housing in which the flexible printed circuit is housed, wherein the housing has a fixing surface to which the short side portions are fixed and an insertion portion into which the long side portions are inserted.
